(19) United States
(12) Patent Application Publication
(10) Pub. No.: US 2026/0123084 A1
(43) Pub. Date: Apr. 30, 2026

(54) IMAGE SENSOR WITH SHARED CAPACITOR

(71) Applicant: SAMSUNG ELECTRONICS CO., LTD., Suwon-si (KR)

(72) Inventors: Soongeul CHOI, Suwon-si (KR); Sungkwan Kim, Suwon-si (KR); Jieun Kim, Suwon-si (KR); Seunghun Shin, Suwon-si (KR); Junetaeg Lee, Suwon-si (KR); Heegeun Jeong, Suwon-si (KR)

(73) Assignee: SAMSUNG ELECTRONICS CO., LTD., Suwon-si (KR)

(21) Appl. No.: 19/219,294

(22) Filed: May 27, 2025

(30) Foreign Application Priority Data
Oct. 28, 2024 (KR) 10-2024-0148983

(51) Int. Cl. H10F 39/00; H01L 23/522; H04N 25/77; H10F 39/18

(52) U.S. Cl. CPC H10F 39/811; H10F 39/182; H10F 39/807; H10W 20/496; H04N 25/77

(57) ABSTRACT

An image sensor includes a substrate having a first surface and a second surface opposite to the first surface, a first unit pixel disposed in the substrate and including a first photodiode and a second photodiode, a second unit pixel disposed in the substrate and including a third photodiode and a fourth photodiode, and a capacitor configured to store first charges generated by the second photodiode and second charges generated by the fourth photodiode. A first light-receiving area of the first photodiode is greater than a second light-receiving area of the second photodiode. A third light-receiving area of the third photodiode is greater than a fourth light-receiving area of the fourth photodiode. The second photodiode is disposed diagonally from the first photodiode on the first surface.

### CROSS-REFERENCE TO RELATED APPLICATIONS

This application claims benefit of priority under 35 U.S.C. § 119 to Korean Patent Application No. 10-2024-0148983, filed on Oct. 28, 2024, in the Korean Intellectual Property Office, the disclosure of which is incorporated by reference herein in its entirety.

### BACKGROUND

### 1. Field

The present disclosure relates generally to image sensors, and more particularly to an image sensor with a shared metal-insulator-metal (MIM) capacitor.

### 2. Description of Related Art

An image sensor may refer to a semiconductor device for converting an optical image into an electrical signal. For example, an image sensor may be implemented using a complementary metal oxide semiconductor (CMOS) type image sensor (CIS), or the like. A CIS may include a plurality of pixel areas, and each pixel area may include at least one photodiode (PD) that may convert incident light into an electrical signal. Recently, as image sensors have been adopted in fields such as, but not limited to, transportation, various methods may have been proposed to accurately capture subjects under various conditions using image sensors (e.g., CIS).

### SUMMARY

One or more example embodiments of the present disclosure provide an image sensor having an improved dynamic range by allowing a plurality of pixel areas to share a single metal-insulator-metal (MIM) capacitor and by increasing a capacity of the MIM capacitor, when compared to a related image sensor.

According to an aspect of the present disclosure, an image sensor includes a substrate having a first surface and a second surface opposite to the first surface, a first unit pixel disposed in the substrate and including a first photodiode and a second photodiode, a second unit pixel disposed in the substrate and including a third photodiode and a fourth photodiode, and a capacitor configured to store first charges generated by the second photodiode and second charges generated by the fourth photodiode. A first size of the first photodiode is greater than a second size of the second photodiode. A third size of the third photodiode is greater than a fourth size of the fourth photodiode. A first light-receiving area of the first photodiode is greater than a second light-receiving area of the second photodiode. A third light-receiving area of the third photodiode is greater than a fourth light-receiving area of the fourth photodiode. The second photodiode is disposed diagonally from the first photodiode on the first surface.

According to an aspect of the present disclosure, an image sensor includes a substrate including a first surface and a second surface opposite to the first surface, a first unit pixel disposed in the substrate and including a first photodiode and a second photodiode, a second unit pixel disposed in the substrate and including a third photodiode and a fourth photodiode disposed in the substrate, and a capacitor configured to store first charges generated by the second photodiode and second charges generated by the fourth photodiode. A first size of the first photodiode being greater than a second size of the second photodiode. A third size of the third photodiode being greater than a fourth size of the fourth photodiode. A first light-receiving area of the first photodiode is greater than a second light-receiving area of the second photodiode. A third light-receiving area of the third photodiode is greater than a fourth light-receiving area of the fourth photodiode. The first photodiode and the second photodiode are configured to receive light wavelengths corresponding to a first color.

According to an aspect of the present disclosure, an image sensor includes a first unit pixel, a second unit pixel, a third unit pixel, and a metal-insulator-metal (MIM) capacitor shared by the first unit pixel, the second unit pixel, and the third unit pixel. The first unit pixel includes a first photodiode, a second photodiode, and a first amplification transistor shared by the first photodiode and the second photodiode. The second unit pixel includes a third photodiode, a fourth photodiode, and a second amplification transistor shared by the third photodiode and the fourth photodiode. The third unit pixel includes a fifth photodiode, a sixth photodiode, and a third amplification transistor shared by the fifth photodiode and the sixth photodiode. The third photodiode is disposed with the first photodiode in a first direction. The fifth photodiode is disposed with the first photodiode in a second direction perpendicular to the first direction. The second photodiode is in contact with the first photodiode in a diagonal direction between the first direction and the second direction.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a schematic block diagram of an image sensor, according to an example embodiment of the present disclosure;

FIGS. 2 and 3 are views schematically illustrating a pixel array structure of an image sensor, according to an example embodiment of the present disclosure;

FIG. 4A is a schematic cross-sectional view illustrating a cross-section of the pixel area group taken along direction I-I′, according to an example embodiment illustrated in FIG. 3;

FIG. 4B is a schematic cross-sectional view illustrating a cross-section of the pixel area group taken along direction II-II′, according to an example embodiment illustrated in FIG. 3;

FIG. 5 is a schematic cross-sectional view illustrating a cross-section of a pixel area group taken along direction III-III′, according to an example embodiment illustrated in FIG. 3;

FIG. 6 is a circuit diagram schematically illustrating a pixel group included in an image sensor, according to an example embodiment illustrated in FIG. 3;

FIG. 7 is a view illustrating an operation of an image sensor, according to an example embodiment of the present disclosure;

FIGS. 8 and 9 are views illustrating an operation of an image sensor, according to example embodiments of the present disclosure;

FIG. 10 is a view illustrating an operation of an image sensor, according to an example embodiment of the present disclosure;

FIG. 11 is a view schematically illustrating a pixel array structure of an image sensor, according to an example embodiment of the present disclosure;

FIG. 12 is a circuit diagram schematically illustrating a pixel group included in an image sensor, according to an example embodiment illustrated in FIG. 11; and

FIGS. 13 to 15 are views schematically illustrating a pixel array structure of an image sensor, according to example embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more. ” Where only one item is intended, the term “one” or similar language is used. For example, the term “a controller” may refer to either a single controller or multiple controllers. When a controller is described as carrying out an operation and the processor is referred to perform an additional operation, the multiple operations may be executed by either a single controller or any one or a combination of multiple controllers.

Hereinafter, various embodiments of the present disclosure are described with reference to the accompanying drawings.

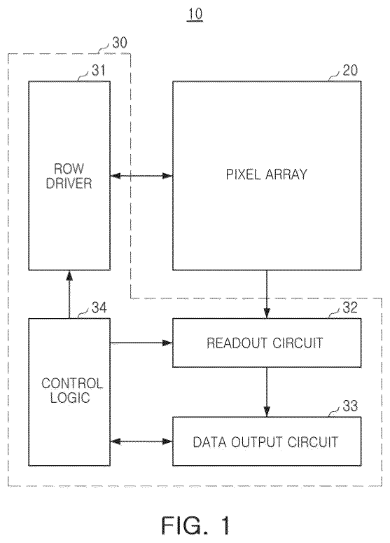

FIG. 1 is a schematic block diagram of an image sensor, according to an example embodiment of the present disclosure.

Referring to FIG. 1, an image sensor 10 may include a pixel array 20 and a peripheral circuit 30. The pixel array 20 may include a plurality of pixels disposed in an array form along a plurality of rows and a plurality of columns. A photoelectric conversion element that may generate charges in response to light (e.g., incident light) may be disposed in each of the plurality of pixels, and the photoelectric conversion element may be connected to a pixel circuit that may generate and/or output a signal corresponding to the charges generated by the photoelectric conversion element.

A pixel may be implemented by the photoelectric conversion element and the pixel circuit. The photoelectric conversion element may include a photodiode formed of a semiconductor material, and/or an organic photodiode formed of an organic material. In an example embodiment, one pixel may include one photodiode. In another example embodiment, one pixel may include a first photodiode and a second photodiode having different light-receiving areas.

The pixel circuit may include a plurality of transistors and a plurality of capacitors. Each capacitor of the plurality of capacitors may store the charges that may be excessively generated by the photodiode, and may be connected to the photodiode through at least one transistor. In an example embodiment, the capacitor may be a metal-insulator-metal (MIM) capacitor. The MIM capacitor may be and/or may include a multi-metal layer structure in which a plurality of metal layers may be stacked.

The peripheral circuit 30 may include one or more circuits for controlling the pixel array 20. For example, the peripheral circuit 30 may include a row driver 31, a readout circuit 32, a data output circuit 33, and a control logic 34. The row driver 31 may drive the pixel array 20 in units of row lines. For example, the row driver 31 may input control signals for controlling an on/off state of each transistor included in the pixel circuit to the pixel array 20 in units of row lines.

Among the plurality of pixels, pixels disposed in the same position along a row direction (horizontal direction in FIG. 1) may share the same column line. For example, pixels disposed in the same position in a column direction (vertical direction in FIG. 1) may be simultaneously selected by the row driver 31 and may output pixel signals through the column lines. In an example embodiment, the readout circuit 32 may simultaneously (e.g., at substantially the same time) receive signals from pixels selected by the row driver 31 through the column lines. For example, the readout circuit 32 may sequentially receive a reset voltage and a signal voltage from each pixel, and the signal voltage may be a voltage in which charges generated by the photodiodes of each pixel are reflected in the reset voltage.

The readout circuit 32 may include a plurality of correlated dual samplers and a plurality of counters. The correlated dual samplers may be connected to the pixels through the column lines. For example, one correlated dual sampler and one counter may be connected to one column line. The correlated dual samplers may read a voltage signal from pixels connected to a row line selected by a row line select signal of the row driver 31 through the column lines. One of the input terminals of each of the correlated dual samplers may be connected to the column lines, and the other input terminal may receive a ramp voltage.

The output terminals of each of the correlated dual samplers may be connected to counters, and the counters may generate a digital pixel signal by counting the time during which an output of each of the correlated dual samplers may be maintained at a predetermined voltage. For example, the counter may count the time during which the ramp voltage input to the correlated dual sampler is greater than a voltage of the column line, and may convert the output of the correlated dual sampler into a digital pixel signal. The data output circuit 33 may include a memory such as, but not limited to, a latch or a buffer circuit, which may temporarily store the digital pixel signal.

The control logic 34 may include a timing controller for controlling an operation timing of the row driver 31, the readout circuit 32 and the data output circuit 33. According to an example embodiment, the control logic 34 may determine a data format output by the data output circuit 33, or may perform preprocessing of data to be output by the data output circuit 33. In an embodiment, the control logic 34 may be physically implemented by analog and/or digital circuits including one or more of a logic gate, an integrated circuit, a microprocessor, a microcontroller, a memory circuit, a passive electronic component, an active electronic component, an optical component, and the like. For example, a field programmable gate array (FPGA) may be used to implement custom logic that may include the functionality of the control logic 34. As another example, a processor in combination with a memory may be used to execute one or more instructions to perform the functionality of the control logic 34.

In an example embodiment of the present disclosure, the readout circuit 32 may perform a readout operation for each of the plurality of pixels. For example, when one of the plurality of row lines is selected, the readout circuit 32 may read a signal corresponding to the charges generated by exposing the pixels arranged along the selected row line to light. In an example embodiment of the present disclosure, the readout circuit 32 may read a signal corresponding to the charges generated in the pixels during one exposure time.

In an example embodiment of the present disclosure, the readout circuit 32 may obtain signals from the pixels under different operating conditions. For example, the readout circuit 32 may perform at least one readout operation under each of the conditions in which conversion gains of each pixel may be high (e.g., a logic high level, “1”, or the like) and/or low (e.g., a logic low level, “0”, or the like). The conversion gains of each pixel may be changed depending on the on/off state of the transistor connected to floating diffusion nodes in each pixel.

As described above, each of the plurality of pixels may include a capacitor. During the exposure time, the charges generated in the photodiode exceeding a full well capacity (FWC) of the photodiode may be moved to the capacitor and stored, and the readout circuit 32 may perform a readout operation of obtaining a signal corresponding to the charges stored in the capacitor. An image may be generated using the signal obtained from the pixels by the readout circuit 32, thus expanding a range of light intensity that the image sensor 10 may express, and thereby, potentially improving a dynamic range of the image sensor 10 when compared a related image sensor.

When the capacity of the capacitor included in the pixel is expanded, the charges generated in the photodiode by exceeding the FWC of the diode during the exposure time moved to the capacitor and stored may increase. Accordingly, the dynamic range of the image sensor 10 may be improved. An area of a metal layer included in the capacitor may be increased or the number of metal layers stacked may be increased, thus expanding the capacity of the capacitor.

In a related image sensor, one photodiode included in one pixel may be connected to one capacitor. That is, each of the plurality of pixels of the image sensor may include one capacitor. Consequently, there may be a limit to increasing the area of the metal layer of the capacitor and/or increasing the number of stacked metal layers due to, for example, space limitations according to the size of the pixel. Therefore, there may be a limit to improving the dynamic range of the image sensor.

In the image sensor 10, according to an example embodiment of the present disclosure, the photodiodes included in the plurality of pixels may be connected to one capacitor. That is, the plurality of photodiodes may share one capacitor. Consequently, the area of the metal layer of the capacitor may be increased by the area of the plurality of pixels. Alternatively or additionally, the number of metal layers stacked on the capacitor may be increased in proportion to the size of the plurality of pixels. As the capacity of the capacitor included in the image sensor 10 increases, the dynamic range of the image sensor 10 may be improved (e.g., increased), when compared to a related image sensor.

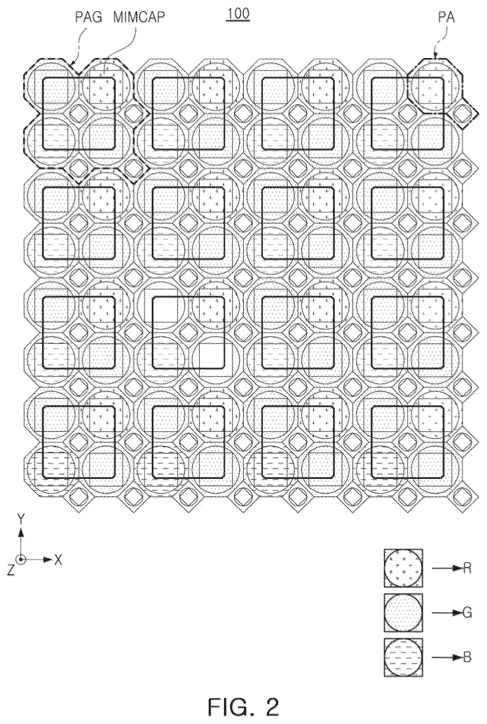

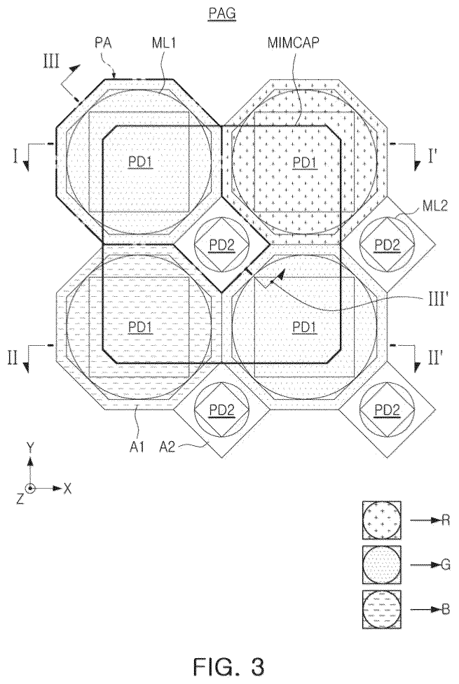

FIGS. 2 and 3 are views illustrating a pixel array structure of an image sensor, according to an example embodiment of the present disclosure.

Referring to FIG. 2, a pixel array 100 of the image sensor, according to an example embodiment of the present disclosure, may include a plurality of pixel areas PA arranged in a first direction (X-axis direction) and a second direction (Y-axis direction). The pixel array 100 may include a plurality of pixel area groups PAG arranged in the first direction and the second direction, and the pixel area group PAG may include a portion of the plurality of pixel areas PA. As the plurality of pixel areas PA are arranged in the first direction and the second direction, photodiodes PD included in the plurality of pixel areas PA may also be arranged in the first direction and the second direction.

As illustrated in FIG. 2, each of the plurality of pixel area groups PAG may include four (4) pixel areas PA arranged in a 2×2 form. However, the present disclosure is limited thereto, and each of the plurality of pixel area groups PAG may include a plurality of pixel areas PA arranged in a M×N form, where M and N a positive integers greater than zero (0), and M and N may be the same or different from each other. In one pixel area group PAG, as the plurality of pixel areas PA may be arranged in a M×N form, the photodiodes PD included in each of the plurality of pixel areas PA may also be arranged in the M×N form.

Each of the plurality of pixel areas PA may include a large photodiode LPD and a small photodiode SPD. For example, a light-receiving area of the large photodiode LPD may be greater than a light-receiving area of the small photodiode SPD. Hereinafter, the large photodiode LPD may be referred to as a first photodiode PD1, and the small photodiode SPD may be referred to as a second photodiode PD2.

In an example embodiment illustrated in FIG. 2, in each of the plurality of pixel areas PA, the first photodiode PD1 and the second photodiode PD2 may be arranged in a diagonal direction, intersecting the first direction and the second direction.

Each of the plurality of pixel areas PA may include a color filter, and the color filter may transmit light wavelengths corresponding to a wavelength of one of red, green, and blues. Each of the plurality of pixel areas PA may include one of a red filter, a green filter, and a blue filter.

FIG. 3 may be an enlarged view of the pixel area group PAG of FIG. 2. Referring to FIG. 3, the pixel area group PAG may include four (4) pixel areas PA arranged in the 2×2 form among the plurality of pixel areas PA in a Bayer pattern. As illustrated in FIG. 3, among the four (4) pixel areas PA disposed in the 2×2 form, two (2) pixel areas PA arranged diagonally may include a green filter, and each of the other two (2) pixel areas PA may include a red filter and a blue filter, respectively.

In an example embodiment illustrated in FIGS. 2 and 3, each of the plurality of pixel areas PA may include a first microlens ML1 and a second microlens ML2. The first microlens ML1 may be disposed above the first photo diode PD1 in a first light-receiving area A1, and the second microlens ML2 may be disposed above the second photo diode PD2 in a second light-receiving area A2.

However, an arrangement of each of the plurality of pixel areas PA may not be limited to that illustrated in FIGS. 2 and 3. For example, the plurality of pixel areas PA may be disposed in a tetra pattern in which four (4) pixel areas PA arranged in the 2×2 form along the first and second directions include color filters of the same color. Additionally, some of the plurality of pixel areas PA may not include a color filter, and/or may include a color filter transmitting light of a color other than red, green, or blue, for example.

In each of the plurality of pixel areas PA, the first photodiode PD1 and the second photodiode PD2 may be connected to a column line through one pixel circuit. The pixel circuit may include a plurality of transistors and capacitors. The charges generated during the exposure time by exceeding the FWC of the first photodiode PD1 and the second photodiode PD2 may be moved to the capacitor and stored. For example, the capacitor may be a metal-insulator-metal (MIM) capacitor MIMCAP having a multi-metal layer structure.

In an example embodiment of the present disclosure, one pixel area group PAG may include one MIM capacitor MIMCAP, so that a plurality of pixel areas PA included in the pixel area group PAG may share one MIM capacitor MIMCAP. For example, all of the first photodiodes PD1 and the second photodiodes PD2 included in the pixel area group PAG may be electrically connected to the one MIM capacitor MIMCAP. In an example embodiment illustrated in FIGS. 2 and 3, four (4) first photodiodes PD1 and four (4) second photodiodes PD2 included in the pixel area group PAG may be electrically connected to the MIM capacitor MIMCAP.

In an example embodiment illustrated in FIGS. 2 and 3, all of the metal layers of the MIM capacitor MIMCAP may have the same shape, or at least one metal layer may have a different shape. An upper surface of the metal layer may be octagonal. However, the present disclosure is not be limited thereto. The metal layers of the MIM capacitor MIMCAP may overlap each other in a third direction.

Referring to FIGS. 2 and 3, the MIM capacitor MIMCAP may overlap four (4) first photodiodes PD1 included in the pixel area group PAG in the third direction (Z-axis direction). The MIM capacitor MIMCAP may overlap at least one of four (4) second photodiodes PD2 included in the pixel area group PAG in the third direction.

According to an example embodiment of the present disclosure, a plurality of pixel areas PA included in the pixel area group PAG may share one MIM capacitor MIMCAP. For example, an area of the metal layer of the MIM capacitor MIMCAP may increase by an area of the plurality of pixel areas PA. Alternatively or additionally, the number of metal layers stacked on the MIM capacitor MIMCAP may be increased in proportion to a size of the plurality of pixel areas PA. As the capacity of the MIM capacitor MIMCAP increases, the image sensor may have an improved (increased) dynamic range, when compared to a related image sensor.

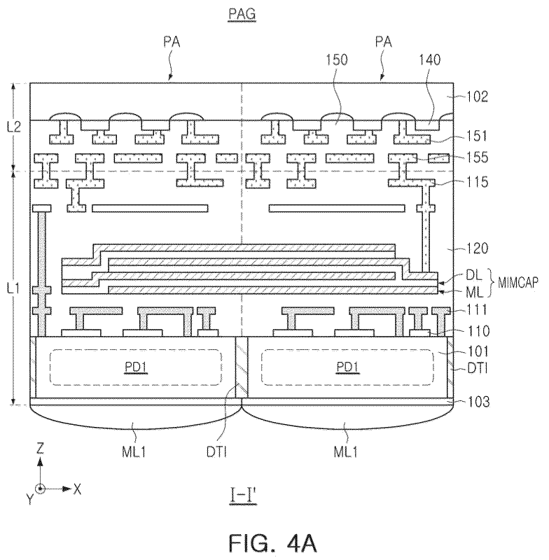

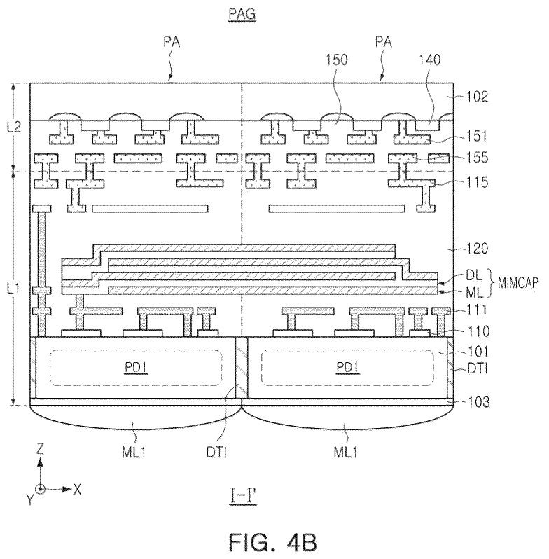

FIG. 4A is a cross-sectional view illustrating a cross-section of a pixel area group in direction I-I′, according to an example embodiment illustrated in FIG. 3. FIG. 4B is a cross-sectional view illustrating a cross-section of a pixel area group in direction II-II′, according to an example embodiment illustrated in FIG. 3. FIG. 5 is a cross-sectional view illustrating a cross-section of a pixel area group in direction III-III′, according to an example embodiment illustrated in FIG. 3.

An image sensor, according to an example embodiment of the present disclosure, may include a first layer L1 and a second layer L2. The first layer L1 and the second layer L2 may be stacked in a third direction (Z-axis direction). The first layer L1 may include a first substrate 101. The first substrate 101 may have a first surface and a second surface, parallel to the first surface. A first interlayer insulating layer 120 may be disposed on the first surface of the first substrate 101. A color filter 103 and a microlens ML1 may be disposed on the second surface of the first substrate 101.

FIGS. 4A, 4B, and 5 may illustrate cross-sections of a pixel area group PAG of an image sensor. The pixel area group PAG may be defined by a device isolation layer DTI. For example, the device isolation layer DTI may be an insulating layer for isolating the pixel area groups PAG from each other.

Referring to FIGS. 2 and 3, a plurality of first photodiodes PD1, a plurality of second photodiodes PD2, and a plurality of transistors 110 may be formed on the first substrate 101. The plurality of transistors 110 may be connected to each other by metal interconnection lines 111, thus providing a pixel circuit connected to the first and second photodiodes PD1 and PD2.

The first and second photodiodes PD1 and PD2 may be disposed in the first substrate 101, and may be defined by a device isolation layer DTI. For example, as shown in FIG. 5, the device isolation layer DTI disposed between the first and second photodiodes PD1 and PD2 may be an insulating film for improving the performance of the image sensor by controlling the movement of electrons in one pixel area PA. Incident light may be incident on one surface of the first layer L1. For example, the incident light may be incident in a first direction from the outside of the image sensor. One surface of the first substrate 101 may be utilized to dispose the plurality of transistors 110 for processing electrical signals generated by the first and second photodiodes PD1 and PD2.

The metal interconnection lines 111 may be disposed in the first interlayer insulating layer 120 formed on the first surface of the first substrate 101. An uppermost-end interconnection line 115 disposed on an uppermost end of the first interlayer insulating layer 120 may be connected to an uppermost-end interconnection line 155 of the second layer L2. The color filter 103, a microlens 105, or the like, may be disposed on the second surface of the first substrate 101.

As an example embodiment illustrated in FIGS. 4A and 4B, the MIM capacitor MIMCAP may be connected to the plurality of transistors 110 and included in the pixel circuit. The MIM capacitor MIMCAP may be disposed in the first interlayer insulating layer 120. The pixel area group PAG may include one MIM capacitor MIMCAP. For example, the plurality of pixel areas PA included in the pixel area group PAG may share one MIM capacitor MIMCAP.

As an example, the MIM capacitor MIMCAP may be a metal-insulator-metal (MIM) capacitor having a multi-metal layer structure including a plurality of metal layers ML and a plurality of dielectric layers DL. The plurality of metal layers ML and the plurality of dielectric layers DL may be intersected and stacked in a third direction. The MIM capacitor MIMCAP may overlap the first photodiodes PD1 included in the pixel area group PAG in the third direction.

Referring to FIG. 4A, a portion of the metal layer ML of the MIM capacitor MIMCAP may be connected to a peripheral circuit of the second layer L2. Accordingly, a certain voltage may be applied to a portion of the metal layer ML. Referring to FIG. 4B, another portion of the metal layer ML of the MIM capacitor MIMCAP may be connected to the first photodiode PD1 and a second photodiode. Accordingly, charges generated by exceeding the FWC of the first and second photodiodes may be stored in the MIM capacitor MIMCAP.

The second layer L2 may include a second substrate 102, and a plurality of transistors 140 may be formed on the second substrate 102. The plurality of transistors 140 may be connected to each other by metal interconnection lines 151 disposed in a second interlayer insulating layer 150, thus providing peripheral circuits for driving the pixel array, such as, but not limited to, a row driver, a readout circuit, or the like. The uppermost-end interconnection line 155 disposed in an uppermost end in the second interlayer insulating layer 150 may be connected to the uppermost-end interconnection line 115 of the first layer L1.

In an example embodiment, a plurality of first conductive pads may be formed on one surface of the first layer L1, and a plurality of second conductive pads may be formed on one surface of the second layer L2. The first and second conductive pads may be disposed to face each other. Accordingly, the one surface of the first layer L1 and the one surface of the second layer L2 may be bonded to each other by hybrid bonding or direct bonding without a connection member such as a metal bump. However, the present disclosure may not be limited thereto.

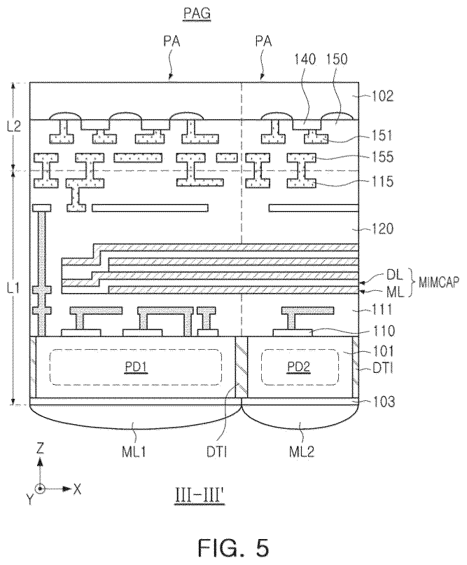

FIG. 6 is a circuit diagram illustrating a pixel group included in an image sensor, according to an example embodiment illustrated in FIG. 3.

In an example embodiment illustrated in FIG. 6, a pixel group PG included in an image sensor may include four (4) pixels PX disposed in a 2×2 form. The pixel PX may include a photodiode PD and a pixel circuit. The photodiode PD may include a first photodiode PD1 and a second photodiode PD2. For example, the first photodiode PD1 may be a large photodiode, and the second photodiode PD2 may be a small photodiode having a smaller light-receiving area than that of the first photodiode PD1.

According to an example embodiment illustrated in FIG. 6, the pixel PX may correspond to a unit pixel UP. The unit pixel may include a large pixel including the first photo diode PD1 and a small pixel including the second photo diode PD2. Example embodiments of the image sensor may be similar to those described above with reference to FIGS. 1 to 4B.

The pixel circuit may include a floating diffusion node FD1, a first transmission transistor TX1, a second transmission transistor TX2, a gain control transistor DRX, a first switch transistor SW1, a third switch transistor SW3, a first reset transistor RX1, a second reset transistor RX2, an amplification transistor SF, and a selection transistor SX. Control signals (e.g., a first transmission control signal TG1, a second transmission control signal TG2, a first reception control signal RG1, a second reception control signal RG2, a first switch control signal SG1, a third switch control signal SG3, a gain control signal DRG, and a selection control signal SEL) for controlling the plurality of transistors included in the pixel circuit may be output by a row driver.

In the pixel circuits of the pixel group PG, according to an example embodiment of the present disclosure, one MIM capacitor MIMCAP may be further included. For example, the pixel circuits of four (4) unit pixels UP may share one MIM capacitor MIMCAP. The photodiodes PD included in the four (4) unit pixels UP may be electrically connected to one MIM capacitor MIMCAP.

Referring to FIG. 6, the pixel circuits of the four (4) unit pixels UP may also share one third switch transistor SW3. The third switch transistor SW3 may be controlled by the third switch control signal SG3. The third switch transistor SW3 may be connected between a first power node and a second power node. When the third switch transistor SW3 is turned on by the third switch control signal SG3, the charges of the MIM capacitor MIMCAP may be discharged.

A floating diffusion node FD1 may be connected to the first photodiode PD1 through the first transmission transistor TX1, and when the first transmission transistor TX1 is turned on by the first transmission control signal TG1, the charges of the first photodiode PD1 may be stored in the floating diffusion node FD1. The floating diffusion node FD1 may be connected to the second photodiode PD2 through the second transmission transistor TX2, the first switch transistor SW1, and the gain control transistor DRX. In an operation of moving the charges generated by the second photodiode PD2 to the floating diffusion node FD1, the second transmission transistor TX2, the first switch transistor SW1 and the gain control transistor DRX may be turned on by a row driver.

The gain control transistor DRX may be connected between the floating diffusion node FD1 and a first node FD3. When the gain control transistor DRX is turned on by a gain control signal DRG, the capacitance of the floating diffusion node FD1 may increase, thereby decreasing a conversion gain of the unit pixel UP. Alternatively, when the gain control transistor DRX is turned off, the conversion gain of the unit pixel UP may increase.

The first switch transistor SW1 may be connected between the first node FD3 and a second node FD2, and the second reset transistor RX2 may be connected between a second node FD2 and a third node N3. The MIM capacitor MIMCAP may be connected between the third node N3 and the first power node. The first power node may be a node supplying a first power voltage VDD1. The second reset transistor RX2 and the MIM capacitor MIMCAP may be connected to each other in series between the second node FD2 and the first power node.

A first reset transistor RX1 may be connected between the first node FD3 and the second power node. The second power node may be a node for supplying a second power voltage VDD2, and may be connected to a drain of the first reset transistor RX1. According to an example embodiment, the second power voltage VDD2 may be the same voltage as the first power voltage VDD1, and/or may be a voltage different from the first power voltage VDD1. In an example embodiment, the second power voltage VDD2 may be higher than the first power voltage VDD1. The third switch transistor SW3 may be connected between the first power node and the second power node.

A gate of the amplification transistor SF may be connected to the floating diffusion node FD1, and the amplification transistor SF may be connected between the third power node and the selection transistor SX. The third power node may be a node supplying a third power voltage VDD3. According to an example embodiment, the third power voltage VDD3 may be equal to at least one of the first power voltage VDD1 or the second power voltage VDD2. In an example embodiment, the third power voltage VDD3 may be equal to the second power voltage VDD2, and may be higher than the first power voltage VDD1. Furthermore, in an example embodiment, the third power voltage VDD3 may be higher than the first power voltage VDD1 and the second power voltage VDD2.

The amplifier transistor SF may operate as a source-follower amplifier, and may generate a signal by amplifying a voltage of the floating diffusion node FD1. The signal generated by the amplifier transistor SF may be output to the column line COL by a turn-on operation of the selection transistor SX. The column line COL may be connected to one of input terminals of the correlated dual sampler, and the correlated dual sampler may transmit a signal output to the column line COL and an output signal determined by a lamp voltage to the counter.

An operation of the unit pixel UP may include a shutter operation, an exposure operation, and a readout operation. In the shutter operation, the charges of the floating diffusion node FD1 and the photodiode PD may be removed, and in the exposure operation, the photodiode PD may be exposed to light for a predetermined exposure time to generate charges. In the readout operation, a voltage of the floating diffusion node FD1 may be amplified and output to the column line COL, and for example, a reset voltage and a signal voltage may be output to the column line COL. The reset voltage may be a voltage that the pixel circuit outputs to the column line COL in a state in which the floating diffusion node FD1 is reset, and the signal voltage may be a voltage that the pixel circuit outputs to the column line COL in a state in which at least some of the charges generated by the photodiode PD are stored in the floating diffusion node FD1.

In an example embodiment of the present disclosure, an operation in which the pixel circuit outputs a voltage to the column line COL after one exposure time may be performed two (2) or more times. For example, the readout operation performed after one exposure time may include a plurality of readout operations performed in sequence. In at least some of the plurality of readout operations, the conversion gains of the unit pixel UP may be set differently from each other.

In an example embodiment, the readout operation may include a high conversion gain (HCG) readout operation executed under the condition in which the unit pixel UP may have a relatively large conversion gain, and a low conversion gain (LCG) readout operation executed under the condition in which the unit pixel UP may have a relatively small conversion gain. Additionally, in an example embodiment, the readout operation may include a lateral overflow integrated capacitor (LOFIC) readout operation of reading a voltage corresponding to charges generated above the FWC of the photodiodes PD1 and PD2 during the exposure time and stored in the MIM capacitor MIMCAP by overflow.

In an example embodiment of the present disclosure, a plurality of unit pixels UP included in a pixel group PG may share a MIM capacitor MIMCAP and one third switch transistor SW3. The MIM capacitor MIMCAP may be formed over a region in which the plurality of unit pixels UP are disposed. Accordingly, an area of the metal layer of the MIM capacitor MIMCAP and/or the number of metal layers stacked on the MIM capacitor MIMCAP may be increased. The capacity of the MIM capacitor MIMCAP may be increased, thereby potentially improving (increasing) the dynamic range of the image sensor, when compared to a related image sensor.

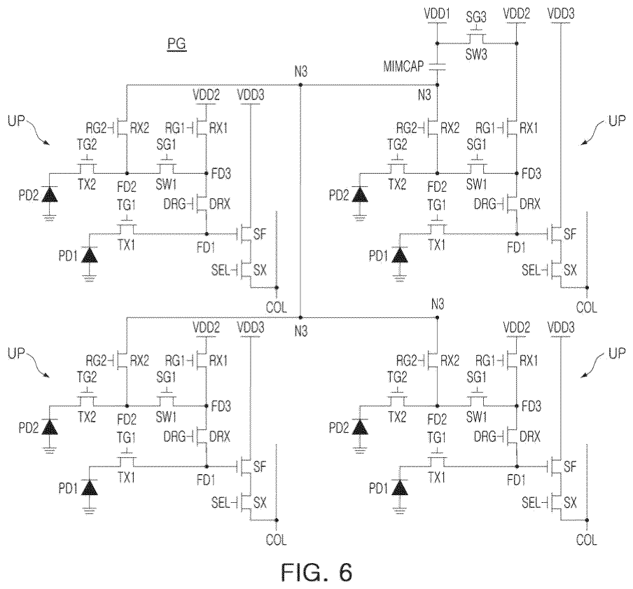

FIG. 7 is a view illustrating an operation of an image sensor, according to an example embodiment of the present disclosure.

FIG. 7 may be a view illustrating an operation of a pixel included in the image sensor, according to an example embodiment of the present disclosure. The pixel may include a first photodiode PD1, a second photodiode PD2 having a smaller light-receiving area than that of the first photodiode PD1, and a pixel circuit. The pixel circuit may include an MIM capacitor shared with another pixel. Example embodiments of the image sensor may be similar to those described above with reference to FIGS. 1 to 6.

In an example embodiment, the pixels included in the pixel array may be disposed in a row direction and a column direction, and may be connected to a row driver in the row direction and may be connected to a readout circuit in the column direction. The row driver may drive pixels arranged in the row direction simultaneously (e.g., at a substantially similar and/or the same time). Accordingly, an operation illustrated in FIG. 7 may be simultaneously executed in two (2) or more pixels arranged in the row direction.

An operation of the pixel may include a shutter operation SH, an exposure time EIT, and a readout operation RD. Image data may be generated by executing the shutter operation SH, the exposure time EIT and the readout operation RD by each pixel.

In the shutter operation SH, a reset operation of removing charges from a photodiode and floating diffusion node of the pixel may be executed. For example, in the shutter operation SH, the photodiode and floating diffusion node may be electrically connected to a power node.

During the exposure time EIT, the photodiode may be exposed to light to generate charges. For example, in the exposure time EIT, the transmission transistor may be maintained in a turn-off state, and the photodiode and the floating diffusion node may be electrically isolated from each other. Accordingly, the charges generated in the photodiode may not move to the floating diffusion node.

However, in an environment in which the intensity of light introduced to the photodiode is significantly strong, charges may be generated by exceeding the FWC of the photodiode. In such an environment, as a voltage of a node in which the photodiode and the transmission transistor are connected decreases due to the excessively generated charges in the photodiode, leakage may occur through a transmission transistor, and the charges generated in the photodiode may move to the floating diffusion node.

In an example embodiment of the present disclosure, the pixel may be designed so that the charges transferred from the photodiode to the floating diffusion node during the exposure time EIT may move to the MIM capacitor connected to the floating diffusion node. Accordingly, in an environment in which the intensity of light is significantly strong, the charges generated by exceeding the FWC of the photodiode may pass through the floating diffusion node and may be stored in the MIM capacitor. Subsequently, in at least one of the first to third readout operations may cause the pixel circuit to output a voltage corresponding to the charges stored in the MIM capacitor. Accordingly, even in an environment having significantly high illuminance, image data in which the subject is accurately expressed may be generated, and a dynamic range of the image sensor may be improved, when compared to a related image sensor.

In an example embodiment illustrated in FIG. 7, the readout operation RD may include a plurality of readout operations RD1 to RD4. Referring to FIG. 7, the first readout operation RD1 may be an operation of reading a pixel signal corresponding to the charges generated by the first photodiode PD1 under the condition in which the pixel has a high conversion gain.

The second readout operation RD2 may be and/or may include an operation of reading the pixel signal corresponding to the charges generated by the first photodiode PD1 under the condition in which the pixel may have a low conversion gain. The third readout operation RD3 may be and/or may include an operation for reading the pixel signal corresponding to the charges generated by the second photodiode PD2 under the condition in which the pixel may have a high conversion gain.

Referring to FIG. 7, the fourth readout operation RD4 may be and/or may include an operation of reading a pixel signal corresponding to charges generated by exceeding the FWC of the second photodiode PD2 and stored in the MIM capacitor. In an example embodiment of the present disclosure, a plurality of pixels may share one MIM capacitor, so that the area in which the MIM capacitor may be formed may be increased. By increasing the area of the metal layer of the MIM capacitor and/or increasing the number of metal layers to be laminated, the capacity of the MIM capacitor may be increased, when compared to a related image sensor.

The MIM capacitor may store more charges generated by exceeding the FWC of a second photodiode PD2. That is, a dynamic range of the image sensor may be improved (increased), when compared to a related image sensor.

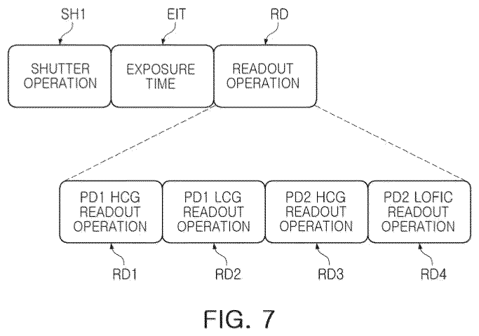

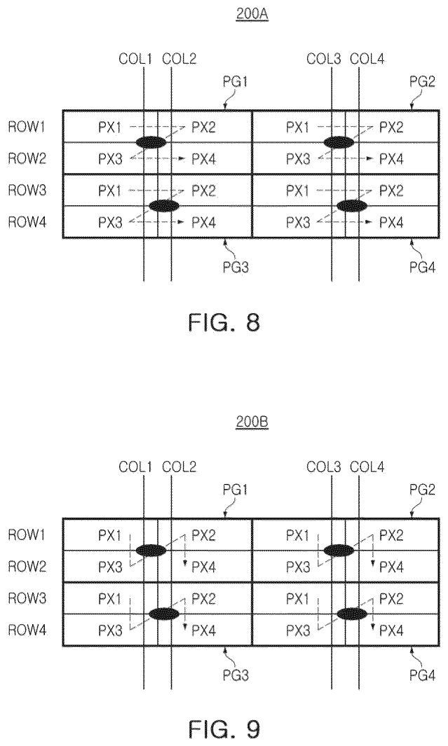

FIGS. 8 and 9 are views illustrating an operation of an image sensor, according to example embodiments of the present disclosure.

FIGS. 8 and 9 may be views illustrating pixel arrays 200A and 200B of the image sensor of an example embodiment of the present disclosure. The pixel arrays 200A and 200B may include a plurality of pixels (e.g., a first pixel PX1, a second pixel PX2, a third pixel PX3, and a fourth pixel PX4, hereinafter generally referred to as “PX”) arranged in an array form in a row direction (e.g., a horizontal direction in FIGS. 8 and 9) and a column direction (e.g., a vertical direction in FIGS. 8 and 9). For example, as shown in FIGS. 8 and 9, the pixel arrays 200A and 200B may be arranged in a plurality of pixel groups (e.g., a first pixel group PG1, a second pixel group PG2, a third pixel group PG3, and a fourth pixel group PG4). Example embodiments of the image sensor may be similar to those described above with reference to FIGS. 1 to 7.

As an example embodiment illustrated in FIGS. 8 and 9, each of the first to fourth pixel groups PG1 to PG4 may include first to fourth pixels PX1 to PX4 arranged in a 2×2 form. The first to fourth pixels PX1 to PX4 of the same pixel group may share one MIM capacitor. Example embodiments of each of the first to fourth pixel groups PG1 to PG4 may be similar to those described above with reference to FIGS. 2 to 6.

Pixels disposed in the same position in the column direction, among the plurality of pixels PX, may share the same row line. As an example embodiment of FIGS. 8 and 9, the first and second pixels PX1 and PX2 may share first and third row lines ROW1 and ROW3. The third and fourth pixels PX3 and PX4 may share second and fourth row lines ROW2 and ROW4.

The first to fourth pixel groups PG1 to PG4 may output pixel signals through different column lines. Among the first to fourth pixel groups PG1 to PG4, pixel groups disposed in the same position in the column direction may output pixel signals through different column lines. Among the first to fourth pixel groups PG1 to PG4, pixel groups disposed in the same position in the row direction may output pixel signals through different column lines.

As an example embodiment illustrated in FIGS. 8 and 9, the first pixel group PG1 may output a pixel signal through a first column line CL1, and the second pixel group PG2 may output a pixel signal through a third column line COL3. The third pixel group PG3 may output a pixel signal through a second column line COL2, and the fourth pixel group PG4 may output a pixel signal through a fourth column line COL4.

Accordingly, the first to fourth pixel groups PG1 to PG4 may be selected simultaneously (e.g., at a substantially similar and/or the same time) and may output pixel signals through the first to fourth column lines COL1 to COL4. For example, pixels disposed in the same positions in each of the first to fourth pixel groups PG1 to PG4 may be selected simultaneously by the row driver, and may output pixel signals through the first to fourth column lines COL1 to COL4. For example, the first pixel PX1 of the first to fourth pixel groups PG1 to PG4 may be selected simultaneously and output pixel signals.

According to an example embodiment illustrated in FIG. 8, in a pixel group, the first to fourth pixels PX1 to PX4 may be selected sequentially. After the first pixels PX1 disposed in the first and third row lines ROW1 and ROW3 are selected, the second pixels PX2 may be selected. Then, after the third pixels PX3 disposed in the second and fourth row lines ROW2 and ROW4 are selected, the fourth pixels PX4 may be selected.

According to an example embodiment illustrated in FIG. 9, in a pixel group, the first, third, second, and fourth pixels PX1, PX3, PX2 and PX4 may be selected in order. After the first pixels PX1 disposed in the first and third row lines ROW1 and ROW3 are selected, the third pixels PX3 disposed in the second and fourth row lines ROW2 and ROW4 may be selected. Then, after the second pixels PX2 disposed in the first and third row lines ROW1 and ROW3 are selected, the fourth pixels PX4 disposed in the second and fourth row lines ROW2 and ROW4 may be selected.

However, an order in which pixels are selected in a pixel group may not be limited thereto. Unlike that as illustrated in FIGS. 8 and 9, pixels disposed in the same position in the row direction, among the pixels, may share the same column line. The row driver may simultaneously drive pixels arranged in the row direction. Accordingly, two (2) or more pixels arranged in the row direction may be simultaneously driven.

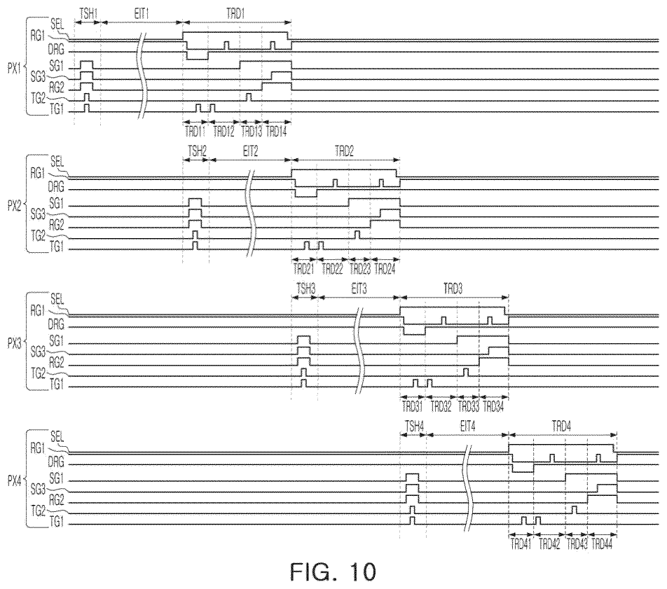

Hereinafter, an operation of one pixel group is described with reference to FIG. 10.

FIG. 10 is a view illustrating an operation of an image sensor, according to an example embodiment of the present disclosure.

FIG. 10 may be a timing diagram illustrating a shutter operation SH, exposure time EIT, and a readout operation RD of one pixel group PG. Example embodiments of the pixel group PG and an operation of the pixel group PG may be similar to those described above in FIGS. 6 to 8. Referring to FIGS. 8 and 10, a single pixel group PG may include first to fourth pixels PX1 to PX4 arranged in the 2×2 form. The first to fourth pixels PX1 to PX4 may share one MIM capacitor and a third switch transistor. In this case, each of the first to fourth pixels PX1 to PX4 may be a unit pixel.

In the operation of the pixel PX described with reference to FIGS. 6 to 9, an on/off state of each of the transistors (e.g., the first transmission transistor TX1, the second transmission transistor TX2, the first reset transistor RX1, the second reset transistor RX2, the first switch transistor SW1, the third switch transistor SW3, the gain control transistor DRX, and the selection transistor SX) included in the pixel PX may be determined, by control signals (e.g., the first transmission control signal TG1, the second transmission control signal TG2, the first reception control signal RG1, the second reception control signal RG2, the first switch control signal SG1, the third switch control signal SG3, the gain control signal DRG, and the selection control signal SEL) output by the row driver.

In each of the first to fourth pixels PX1 to PX4, the shutter operation SH, the exposure time EIT, and the readout operation RD may be sequentially performed. According to an example embodiment illustrated in FIG. 10, shutter operation times (e.g., a first shutter operation time TSH1, a second shutter operation time TSH2, a third shutter operation time TSH3, and a fourth shutter operation time TSH4), exposure times (e.g., a first exposure time EIT1, a second exposure time EIT2, a third exposure time EIT3, and a fourth exposure time EIT4), and readout times (e.g., a first readout time TRD1, a second readout time TRD2, a third readout time TRD3, a fourth readout time TRD4) of the first to fourth pixels PX1 to PX4 may be the same as each other.

Referring to FIGS. 8 and 10, the first to fourth pixels PX1 to PX4 may be sequentially selected. For example, the operations of the first to fourth pixels PX1 to PX4 may be sequentially triggered. According to an example embodiment illustrated in FIG. 10, the sum of the time required for the shutter operation SH and the exposure time EIT may be the same as the time required for the readout operation RD.

After the exposure time EIT for a previously selected pixel PX is completed, the shutter operation SH for a next selected pixel PX may be triggered. That is, after the readout operation RD for the previously selected pixel PX is completed, the readout operation RD for the next selected pixel PX may be triggered. For example, the readout operation RD for the pixel PX may not be performed simultaneously. Hereinafter, the operation of the first pixel PX1 is described with reference to FIG. 6.

During the first shutter operation time TSH1 of the first pixel PX1, the first transmission transistor TX1, the second transmission transistor TX2, the first switch transistor SW1, the third switch transistor SW3, the first reset transistor RX1, the second reset transistor RX2, and the gain control transistor DRX may be turned on, and the selection transistor SX may be turned off.

Accordingly, the charges of the first photodiode PD1, the second photodiode PD2, the floating diffusion node FD1, and the MIM capacitor MIMCAP may be removed by the first power supply voltage VDD1 and the second power supply voltage VDD2. That is, the charges of the first photodiode PD1 may be removed by the first reset transistor RX1 and the second power supply voltage VDD2, and the charges of the second photodiode PD2 may be removed by the second reset transistor RX2 and the first power supply voltage VDD1.

During the first exposure time EIT1, the first reset transistor RX1 and the gain control transistor DRX may be turned on, and the remaining transistors (e.g., the first transmission transistor TX1, the second transmission transistor TX2, the first switch transistor SW1, the third switch transistor SW3, the selection transistor SX, and the second reset transistor RX2) may all be turned off. The first photodiode PD1 and the second photodiode PD2 may generate charges in response to light, and the generated charges may remain in the first photodiode PD1 and the second photodiode PD2. However, in an environment in which significantly strong light is introduced, charges may be generated beyond the FWC of the first photodiode PD1 and the second photodiode PD2. Hereinafter, for convenience of explanation, the charges generated beyond the FWC in each of the first photodiode PD1 and the second photodiode PD2 may be referred to as excess charges.

For example, when the excess charges are generated in the second photodiode PD2, a voltage of a node where the second transmission transistor TX2 and the second photodiode PD2 are connected to each other, for example, a source of the second transmission transistor TX2, may decrease due to the charges. Accordingly, even though the second transmission control signal TG2 input to the gate of the second transmission transistor TX2 is maintained at a voltage corresponding to the logic row, a charge movement path may be formed through the channel of the second transmission transistor TX2. Excess charges of the second photodiode PD2 may be moved to the second node FD2.

In an example embodiment of the present disclosure, the voltage of the source of the second reset transistor RX2 may decrease due to the charges of the second node FD2. Accordingly, even though the second reset control signal RX2 input to a gate of the second reset transistor RX2 is maintained at a voltage corresponding to the logic row, a charge movement path may be formed through a channel of the second reset transistor RX2, and the excess charge moved to the second node FD2 may move to the MIM capacitor MIMCAP and be stored. The first switch transistor SW1 may be turned off so that the excess charges are not moved to the floating diffusion node FD1.

In an example embodiment illustrated in FIG. 10, the first pixel PX1 may execute the first readout operation RD1 after the first exposure time EIT1 has elapsed. As described above with reference to FIG. 7, the readout operation RD may include the plurality of readout operations RD1 to RD4. Referring to FIG. 10, the first readout operation RD1 may include multiple readout operations RD11 to RD14.

Referring to FIG. 10, during a first readout time TRD11 of the first pixel PX1, the selection transistor SX may be turned on first by a selection control signal SEL, and the first reset transistor RX1 and the gain control transistor DRX may be turned off. When the selection transistor SX is turned on, the amplification transistor SF may amplify the voltage of the floating diffusion node FD1 to output a reset voltage.

Referring to FIG. 10, the reset voltage may be output twice. A first reset voltage may be output in a state in which the gain control transistor DRX is turned off, and the second reset voltage may be output in a state in which the gain control transistor DRX is turned on. The first reset voltage may be a reset voltage output under a condition in which the first pixel PX1 has a high conversion gain, and the second reset voltage may be a reset voltage output under a condition in which the first pixel PX1 has a low conversion gain.

When the reset voltage is output, as illustrated in FIGS. 7 and 10, the first transmission transistor TX1 may be turned on, and the charges of the first photodiode PD1 may be moved to the floating diffusion node FD1. The amplification transistor SF may output a signal voltage for amplifying a voltage of the floating diffusion node FD1 to the column line COL. The readout circuit connected to the column line COL may calculate a first pixel signal from a difference between the reset voltage and the signal voltage.

The first pixel signal may be a signal for covering a relatively low first range of illumination. Referring to FIG. 10, while the first pixel PX1 outputs the signal voltage to the column line COL, the gain control transistor DRX may be turned off. Accordingly, the capacitance of the floating diffusion node FD1 may be kept sufficiently small, and the first pixel PX1 may output a signal voltage under a condition of high conversion gain.

Referring to FIG. 10, the first transmission transistor TX1 may be turned on by the first transmission control signal TG1, so that some of the charges of the first photodiode PD1 may be moved to the floating diffusion node FD1. Since the gain control transistor DRX may be turned off to separate the first node FD3 and the floating diffusion node FD1, charges may be stored in the floating diffusion node FD1 having a relatively small capacitance, and a signal voltage may be output to the column line COL under a high conversion gain condition.

Subsequently, during the second readout time TRD12 of the first pixel PX1, the gain control transistor DRX may be turned on and the first node FD3 may be connected to the floating diffusion node FD1. Accordingly, during the second readout time TRD12 of the first pixel PX1, the capacitance of the gain control transistor DRX and the capacitance of the first node FD3 may be added to the capacitance of the floating diffusion node FD1, so that the first pixel PX1 may output a signal under a low conversion gain condition.

In a state in which the gain control transistor DRX is turned on and the capacitance of the floating diffusion node FD1 increases, the first transmission transistor TX1 may be turned on so that residual charges remaining in the first photo diode PD1 may be moved to the floating diffusion node FD1. Referring to FIG. 10, the residual charges remaining in the first photo diode PD1 and not moving to the floating diffusion node FD1 during a first readout time MRD11 of the first pixel PX1, may move to the floating diffusion node FD1 when the first transmission transistor TX1 is turned on during a second readout time MRD12 of the first pixel PX1.

The capacitance of the floating diffusion node FD1 may be a value obtained by adding an intrinsic capacitance of the floating diffusion node FD1 to the capacitance of the first node FD3 and the gain control transistor DRX. Accordingly, during the second readout time TRD12 of the first pixel PX1, the signal voltage may be output to the column line COL under the condition in which the first pixel PX1 has a low conversion gain.

Since at least a portion of the charges of the first photodiode PD1 may have already moved to the floating diffusion node FD1 during the first readout time TRD11 of the first pixel PX1, the reset voltage may not be output before the signal voltage during the second readout time TRD12 of the first pixel PX1. In an example embodiment of the present disclosure, as described above, the reset voltage may be output twice during the first readout time TRD11 of the first pixel PX1, and the first reset voltage may be a reset voltage output under the condition in which the first pixel PX1 has a high conversion gain. The readout circuit may produce a second pixel signal under a low conversion gain condition using a difference between the first reset voltage output by the first pixel PX1 during the first readout time TRD11 of the first pixel PX1 and a signal voltage output by the first pixel PX1 during the second readout time TRD12 of the first pixel PX1. The second pixel signal may be a signal for covering a second range of illumination higher than a first range.

Referring to FIG. 10, the first switch transistor SW1 may be turned on after the second readout time TRD12 of the first pixel PX1 is terminated. Additionally, the first reset transistor RX1 may be turned on to reset the floating diffusion node FD1. Accordingly, at a third readout time TRD13 of the first pixel PX1, the first pixel PX1 may first output a reset voltage. When the reset voltage is output, as illustrated in FIG. 10, the second transmission transistor TX2 may be turned on.

Accordingly, as the charges of the second photodiode PD2 may be moved to the second node FD2 and the first switch transistor SW1 is maintained in a turned-on state, the charges moved to the second node FD2 may be moved to the third node FD3. The amplification transistor SF may amplify a voltage of the third node FD3 to output a signal voltage. The readout circuit may calculate a third pixel signal using a difference between the reset voltage and the signal voltage output by the first pixel PX1 at the third readout time TRD13 of the first pixel PX1. The third pixel signal may be a signal for covering a third range of illumination higher than the second range.

Referring to FIG. 10, during a fourth readout time TRD14 of the first pixel PX1, the first switch transistor SW1, the second reset switch transistor RX2, and the gain control transistor DRX may be turned on. As the first switch transistor SW1, the second reset switch transistor RX2 and the gain control transistor DRX may be turned on, the charges stored in the MIM capacitor MIMCAP may move to the floating diffusion node FD1. A signal voltage corresponding to the charges stored in the MIM capacitor MIMCAP may be output through the column line COL.

When the signal voltage is output, the row driver may turn on the first reset transistor RX1 and the third switch transistor SW3. Accordingly, a reset operation in which the charges of the floating diffusion node FD1 and the MIM capacitor MIMCAP are removed, and a reset voltage may be output through the column line COL. In the fourth readout time TRD14 of the first pixel PX1, the signal voltage may be output before the reset voltage. The readout circuit may calculate a fourth pixel signal using a difference between the reset voltage output by the first pixel PX1 and the signal voltage. The fourth pixel signal may be a signal for covering the fourth range of illumination higher than the third range.

As described above, the MIM capacitor MIMCAP may store excess charge generated by exceeding the FWC in the first photodiode PD1 during the first exposure time EIT1. Under the condition in which light strong enough to generate charges exceeding the FWC of the first photodiode PD1 is introduced into the first pixel PX1, the charges may be stored in the MIM capacitor MIMCAP. Accordingly, by utilizing the fourth pixel signal generated by the charges stored in the MIM capacitor MIMCAP, it may be possible to cover significantly high illuminances.

Referring to FIG. 10, when a first shutter operation SH1 and the first exposure time EIT1 of the first pixel PX1 are completed, a second shutter operation SH2 of the second pixel PX2 may be triggered. When the first readout operation RD1 of the first pixel PX1 is completed, the second readout operation RD2 of the second pixel PX2 may be executed. The second shutter operation SH2, a second exposure time EIT2, and the second readout operation RD2 of the second pixel PX2 may be executed similarly to the first pixel PX1.

Referring to FIG. 10, when the second shutter operation SH2 and the second exposure time EIT2 of the second pixel PX2 are completed, a third shutter operation SH3 of the third pixel PX3 may be triggered. When the second readout operation RD2 of the second pixel PX2 is completed, the third readout operation RD3 of the third pixel PX3 may be executed. The third shutter operation SH3, a third exposure time EIT3, and the third readout operation RD3 of the third pixel PX3 may be executed similarly to the first pixel PX1.

Referring to FIG. 10, when the third shutter operation SH3 and the third exposure time EIT3 of the third pixel PX3 are completed, a fourth shutter operation SH4 of the fourth pixel PX4 may be triggered. When the third readout operation RD3 of the third pixel PX3 is completed, the fourth readout operation RD4 of the fourth pixel PX4 may be executed. The fourth shutter operation SH4, a fourth exposure time EIT4, and the fourth readout operation RD4 of the fourth pixel PX4 may be executed similarly to the first pixel PX1.

In an example embodiment, an output image may be generated using the first to fourth pixel signals of the first to fourth pixels PX1 to PX4. At least some of the signals may be merged or an average of at least some of the signals may be calculated to generate an output image. However, the present disclosure may not be limited thereto.

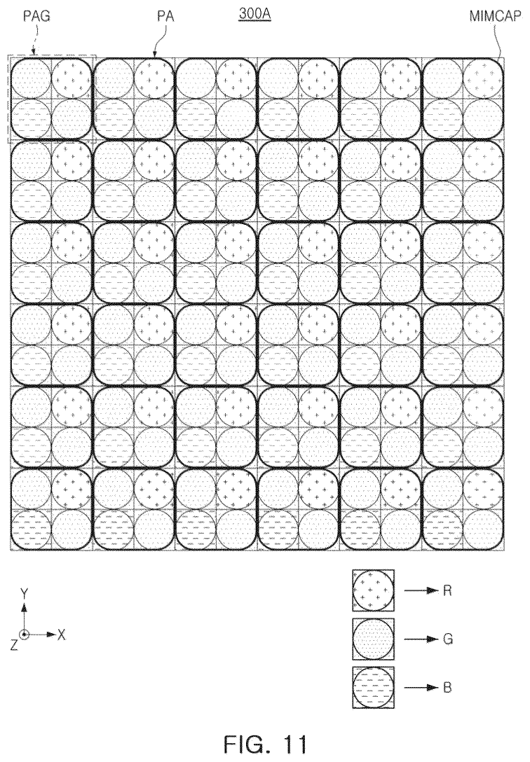

FIG. 11 is a view schematically illustrating a pixel array structure of an image sensor, according to an example embodiment of the present disclosure.

Referring to FIG. 11, a pixel array 300A of the image sensor, according to an example embodiment of the present disclosure, may include a plurality of pixel areas PA arranged in a first direction (X-axis direction) and a second direction (Y-axis direction). The pixel array 300A may include a plurality of pixel area groups PAG arranged in the first direction and the second direction, and the pixel area group PAG may include a portion of the plurality of pixel areas PA.

In an example embodiment illustrated in FIG. 11, each of the plurality of pixel area groups PAG may include four (4) pixel areas PA arranged in a 2×2 form. However, the present disclosure is not limited thereto, and each of the plurality of pixel area groups PAG may include a plurality of pixel areas PA arranged in an M×N form.

According to an example embodiment illustrated in FIG. 11, each of the plurality of pixel areas PA may include one photodiode. Each of the plurality of pixel areas PA may include a color filter, and the color filter may transmit light wavelengths corresponding to a wavelength of one of red, green, or blue. Each of the plurality of pixel areas PA may include one of a red filter, a green filter, and a blue filter. However, the present disclosure is not limited in this regard.

Referring to FIG. 11, a pixel area group PAG may include four (4) pixel areas PA arranged in the 2×2 form, among the plurality of pixel areas PA, in a Bayer pattern. As illustrated in FIG. 11, among the four (4) pixel areas PA arranged in the 2×2 form, two (2) pixel areas PA arranged diagonally may include a green filter, and each of the other two (2) pixel areas PA may include a red filter and a blue filter. However, the present disclosure is not limited in this regard, and the pixel areas may be arranged in other patterns.

In an example embodiment of the present disclosure, one pixel area group PAG may include one MIM capacitor MIMCAP, so that the plurality of pixel areas PA included in the pixel area group PAG may share one MIM capacitor MIMCAP. For example, all photodiodes included in the pixel area group PAG may be electrically connected to the one MIM capacitor MIMCAP. As an example embodiment illustrated in FIG. 11, four (4) photodiodes included in a pixel area group PAG may be electrically connected to the MIM capacitor MIMCAP.

In an embodiment, the area of the metal layer of the MIM capacitor MIMCAP may be increased by the area of the plurality of pixel areas PA. Alternatively or additionally, the number of metal layers stacked on the MIM capacitor MIMCAP may be increased in proportion to the size of the plurality of pixel areas PA. As the capacity of the MIM capacitor MIMCAP is increased, the image sensor may have an improved dynamic range, when compared to a related image sensor.

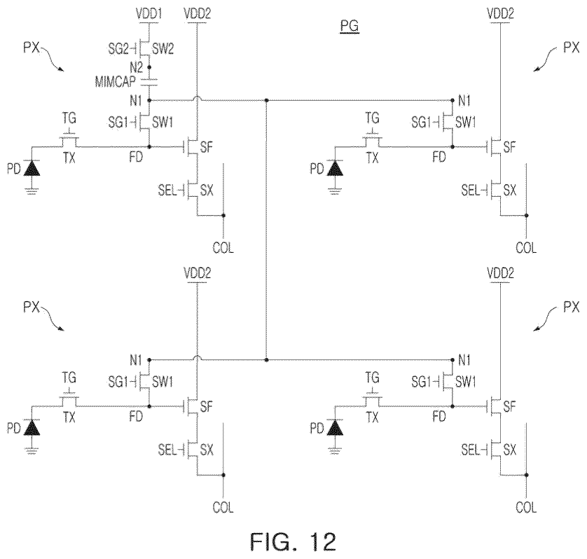

FIG. 12 is a circuit diagram schematically illustrating a pixel group included in an image sensor, according to an example embodiment illustrated in FIG. 11.

In an example embodiment illustrated in FIG. 12, the pixel group PG included in the image sensor may include four (4) pixels PX arranged in the 2×2 form. The pixel PX may include a photodiode PD and a pixel circuit. Example embodiments of the image sensor may be similar to those described above with reference to FIG. 11.

The pixel circuit may include a floating diffusion node FD, a transmission transistor TX, a first switch transistor SW1, an amplification transistor SF, and a selection transistor SX. Control signals (e.g., a transmission control signal TG, a first switch control signal SG1, and a selection control signal SEL) for controlling a plurality of transistors included in the pixel circuit may be output by the row driver.

In the pixel circuits of the pixel group PG, according to an example embodiment of the present disclosure, one MIM capacitor MIMCAP may be further included. For example, the pixel circuits of four (4) pixels PX may share one MIM capacitor MIMCAP. The photodiodes PD included in the four (4) pixels PX may be electrically connected to one MIM capacitor MIMCAP.

Referring to FIG. 12, the pixel circuits of the four (4) pixels PX may also share one second switch transistor SW2. The second switch transistor SW2 may be controlled by a second switch control signal SG2. The second switch transistor SW2 may be connected between the first power node and a second node N2. When the second switch transistor SW2 is turned on by the second control signal SG3, the charges of the MIM capacitor MIMCAP may be discharged.

The floating diffusion node FD may be connected to the photodiode PD through the transmission transistor TX. When the transmission transistor TX is turned on by the transmission control signal TG, the charges of the photodiode PD may be stored in a floating diffusion node FDN.

In an example embodiment illustrated in FIG. 12, the first switch transistor SW1 may be connected between a first node N1 and the floating diffusion node FD, and the first node N1 may be connected to a drain of the first switch transistor SW1. When the first switch transistor SW1 is turned on by a first switch control signal SG1, the capacitance of the floating diffusion node FD may increase, thereby decreasing the conversion gain of the pixel PX. Alternatively, when the first switch transistor SW1 is turned off, the conversion gain of the pixel PX may increase.

The MIM capacitor MIMCAP may be connected between the first node N1 and the second node N2, and the second switch transistor SG2 may be connected between the first power node and the second node N2. The first power node may be a node supplying the first power voltage VDD1. Between the first node N1 and the first power node, the second switch transistor SW2 and the MIM capacitor MIMCAP may be connected to each other in series.

The amplification transistor SF may be connected to the floating diffusion node FDN, and the amplification transistor SF may be connected between the second power supply node and the selection transistor SX. The second power supply node may be a node supplying the second power supply voltage VDD2. According to an example embodiment, the first power supply voltage VDD1 may be the same as or different from the second power supply voltage VDD2.

The amplification transistor SF may operate as a source-follower amplifier, and may generate a signal by amplifying the voltage of the floating diffusion node FD. The signal generated by the amplification transistor SF may be output to the column line COL by the turn-on operation of the selection transistor SX. The column line COL may be connected to one of input terminals of the correlated double sampler, and the correlated double sampler may transmit the signal output to the column line COL and may transmit an output signal determined by the ramp voltage to the counter.

An operation of the pixel PX may include, but not be limited to, a shutter operation, an exposure operation, a readout operation, or the like. In the shutter operation, the charges of the floating diffusion node FD and the photodiode PD may be removed, and in the exposure operation, the photodiode PD may be exposed to light for a predetermined exposure time to generate charges. In the readout operation, a voltage of the floating diffusion node FD may be amplified and may be output to the column line COL, and for example, the reset voltage and the signal voltage may be output to the column line COL. The reset voltage is a voltage that the pixel circuit outputs to the column line COL in a state in which the floating diffusion node FD is reset, and the signal voltage may be a voltage that the pixel circuit outputs to the column line COL in a state in which at least portions of the charges generated in the photodiode PD are stored in the floating diffusion node FD.

In an example embodiment of the present disclosure, an operation in which the pixel circuit outputs the voltage to the column line COL after one exposure time may be executed two (2) or more times. For example, a readout operation executed after one exposure time may include a plurality of readout operations executed sequentially. In at least some of the plurality of readout operations, the conversion gain of the pixel PX may be set differently.

In an example embodiment, the readout operation may include an HCG readout operation executed under the condition in which the pixel PX has the relatively large conversion gain, and an LCG readout operation executed under the condition in which the pixel PX has the relatively small conversion gain. Furthermore, in an example embodiment, the readout operation may include an LOFIC readout operation of reading a voltage corresponding to charges generated at a level equal to or greater than the FWC of the photodiode PD during the exposure time and stored in the MIM capacitor MIMCAP by overflow. Hereinafter, the operation of the pixel group PG is described.

The plurality of pixels PX included in the pixel group PG may be sequentially selected, and operations thereof may be sequentially triggered. In each pixel PX, the shutter operation SH, the exposure time EIT, and the readout operation RD may be sequentially executed. Image data may be generated by each pixel by executing the shutter operation SH, the exposure time EIT and the readout operation RD. Example embodiments thereof may be similar to those described above with reference to FIG. 10.

During the shutter operation time TSH of the pixel PX, the transmission transistor TX, the first switch transistor SW1, and the second switch transistor SW2 may be turned on, and the selection transistor SX may be turned off. Accordingly, the charges of the photodiode PD, the floating diffusion node FD and the MIM capacitor MIMCAP may be removed by the first power supply voltage VDD1 and the second power supply voltage VDD2.

During the exposure time EIT, all the transistors may be turned off. The photodiode and the floating diffusion node may be electrically separated from each other. Accordingly, the charges generated in the photodiode may not move to the floating diffusion node. The photodiode PD may generate charges in response to light, and the generated charges may remain in the photodiode PD. However, in an environment in which significantly strong light may be input, charges may be generated at a level equal to or greater than the FWC of the photodiode PD. Hereinafter, for convenience of explanation, the charges generated beyond the FWC in the photodiode PD are referred to as excess charges.

For example, when excess charges are generated in the photodiode PD, a voltage of a node in which the transmission transistor TX and the photodiode PD are connected to each other, for example, a source of the transmission transistor TX, may decrease due to the charges. Accordingly, even though a transmission control signal TG input to a gate of the transmission transistor TX is maintained at a voltage corresponding to the logic row, a path for the charges may be formed through a channel of the transmission transistor TX, and the excess charges of the photodiode PD may be moved to the floating diffusion node FD.

In an example embodiment of the present disclosure, a voltage of a source of the first switch transistor SW1 may decrease due to the charges of the floating diffusion node FD. Accordingly, even though the first switch control signal SG1 input to the gate of the first switch transistor SW1 is maintained at a voltage corresponding to the logic row, a charge movement path may be formed through a channel of the first switch transistor SW1. The excess charge moved to the first node N1 may be moved to the MIM capacitor MIMCAP and stored.

In an example embodiment illustrated in FIG. 12, the pixel PX may execute a readout operation RD after the exposure time EIT has elapsed. The readout operation RD may include a plurality of readout operations. For example, the readout operation RD may include first and second readout operations RD1 and RD2.

During the first readout time TRD1 of the pixel PX, first, the selection transistor SX may be turned on by the selection control signal SEL, so that a reset voltage may be output through the column line COL. When the reset voltage is output, the transmission transistor TX may be turned on so that the charges generated in the photodiode PD during the exposure time EIT may be moved to the floating diffusion node FD. The amplification transistor SF may output a signal voltage for amplifying the voltage of the floating diffusion node FD to the column line COL. The readout circuit connected to the column line COL may calculate a first pixel signal from a difference between the reset voltage and the signal voltage. In this case, the capacitance of the floating diffusion node FD may be maintained to be small, so that the pixel PX may have a high conversion gain.

Subsequently, during the second readout time TRD2 of the pixel PX, as the second switch transistor SW2 is turned on, the charges stored in the MIM capacitor MIMCAP may be moved to the floating diffusion node FD. Through the column line COL, a signal voltage corresponding to the charges stored in the MIM capacitor MIMCAP may be output.

When the signal voltage is output, the row driver may turn on the second switch transistor SW2. Accordingly, a reset operation in which the charges of the floating diffusion node FD and the MIM capacitor MIMCAP are removed may be executed, and the reset voltage may be output through the column line COL. The readout circuit connected to the column line COL may calculate a second pixel signal from a difference between the reset voltage and the signal voltage. In this case, the capacitance of the floating diffusion node FD may be maintained to be large, so that the pixel PX may have low conversion gain.

In an example embodiment of the present disclosure, the plurality of pixels PX included in the pixel group PG may share the MIM capacitor MIMCAP and one second switch transistor SW2. The MIM capacitor MIMCAP may be formed over a region in which the plurality of pixels PX are disposed. Accordingly, an area of a metal layer of the MIM capacitor MIMCAP may be increased and/or the number of metal layers stacked on the MIM capacitor MIMCAP may be increased. Since the capacity of the MIM capacitor MIMCAP may be increased, thereby potentially improving the dynamic range of the image sensor, when compared to a related image sensor.

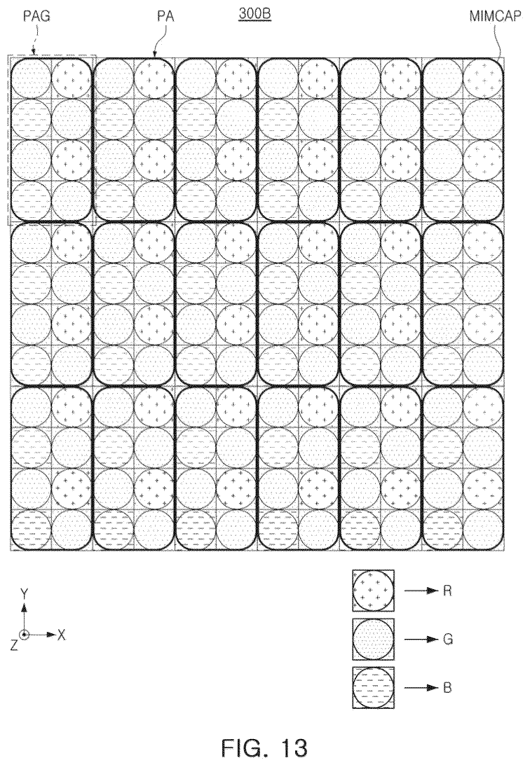

FIGS. 13 to 15 are views schematically illustrating a pixel array structure of an image sensor, according to example embodiments of the present disclosure.

Referring to FIGS. 13 to 15, pixel arrays 300B, 300C and 300D of the image sensor, according to example embodiments of the present disclosure, may include a plurality of pixel areas PA arranged in the first direction (X-axis direction) and the second direction (Y-axis direction). The pixel arrays 300B, 300C and 300D may include a plurality of pixel area groups PAG arranged in the first direction and the second direction, and the pixel area group PAG may include portions of the plurality of pixel areas PA.

As compared to the pixel array 300A of FIG. 12, the pixel arrays 300B, 300C and 300D of FIGS. 13 to 15 may differ from each other in the number and/or arrangement of the plurality of pixel areas PA included in each of the plurality of pixel area groups PAG. Example embodiments of the image sensor illustrated in FIGS. 13 to 15 may be similar to those described above in FIGS. 1 to 12. Hereinafter, the differences in the number and/or arrangement of the plurality of pixel areas PA included in each of the plurality of pixel area groups PAG are described.

First, referring to FIG. 13, each of the plurality of pixel area groups PAG may include eight (8) pixel areas PA arranged in a 4×2 form, and the pixel area PA may include one photodiode. One pixel area group PAG may include one MIM capacitor MIMCAP, so that eight (8) pixel areas PA included in the pixel area group PAG may share one MIM capacitor MIMCAP. In other words, eight (8) photodiodes included in the pixel area group PAG may be electrically connected to the one MIM capacitor MIMCAP.

Consequently, an area of a metal layer of the MIM capacitor MIMCAP may be increased by an area of the eight (8) pixel areas PA. Alternatively or additionally, the number of metal layers stacked on the MIM capacitor MIMCAP may be increased in proportion to the size of the eight (8) pixel areas PA. The capacity of the MIM capacitor MIMCAP may be increased beyond the capacity of the MIM capacitor MIMCAP of FIG. 11. Accordingly, the dynamic range of FIG. 13 may be further improved than the dynamic range of FIG. 11.

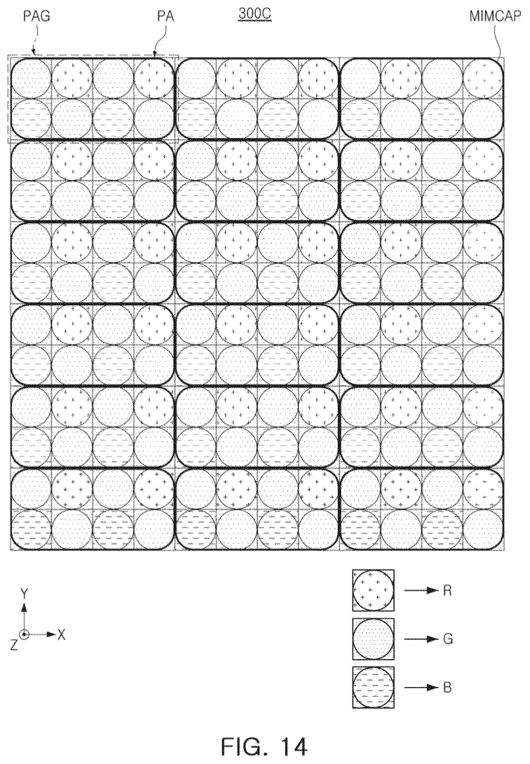

Referring to FIG. 14, each of the plurality of pixel area groups PAG may include eight (8) pixel areas PA arranged in a 2×4 form, and the pixel area PA may include one photodiode. As compared to FIG. 13, arrangements of the eight (8) pixel areas PA may be different from each other.

The eight (8) pixel areas PA included in one pixel area group PAG may share one MIM capacitor MIMCAP. An area of the metal layer of the MIM capacitor MIMCAP may be increased by the area of the eight (8) pixel areas PA. A dynamic range of FIG. 14 may be further improved than the dynamic range of FIG. 11, and may be the same as the dynamic range of FIG. 13.

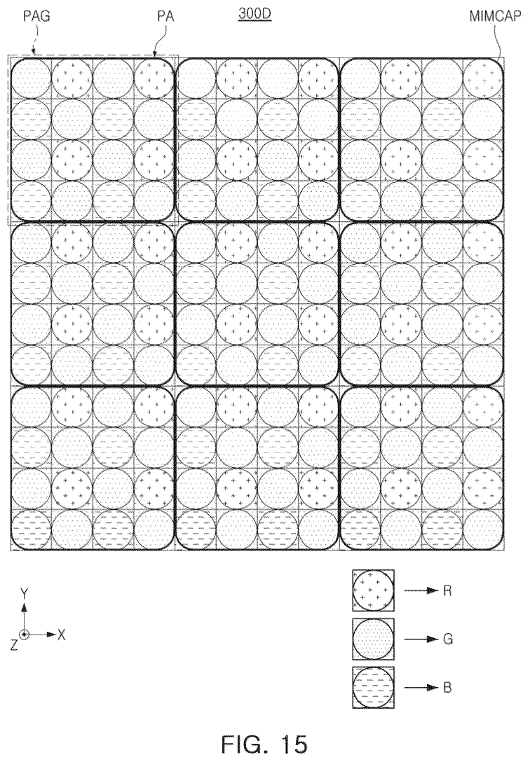

Referring to FIG. 15, each of the plurality of pixel area groups PAG may include 16 pixel areas PA arranged in a 4×4 form, and the pixel area PA may include one photodiode. One pixel area group PAG may include one MIM capacitor MIMCAP, and the 16 pixel areas PA included in the pixel area group PAG may share one MIM capacitor MIMCAP. For example, the sixteen (16) photodiodes included in the pixel area group PAG may be electrically connected to the one MIM capacitor MIMCAP.

Consequently, the area of the metal layer of the MIM capacitor MIMCAP may be increased by the area of the 16 pixel areas PA. Alternatively or additionally, the number of metal layers stacked on the MIM capacitor MIMCAP may be increased in proportion to the size of the 16 pixel areas PA. The capacity of the MIM capacitor MIMCAP may be increased beyond the capacity of each of the MIM capacitors MIMCAP of FIG. 11, FIG. 13 and FIG. 15. Accordingly, the dynamic range of FIG. 15 may be further improved than the dynamic ranges of FIGS. 11, 13 and 15.

However, the number and/or arrangement of the plurality of pixel areas PA included in each of the pixel area groups PAG may not be limited thereto. Additionally, the pixel area PA may include a large photo diode LPD and a small photo diode SPD, similarly to the example embodiments of FIGS. 2 to 10.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes may be construed as being included in the scope of the present disclosure.

What is claimed is:

1. An image sensor, comprising:
a substrate having a first surface and a second surface opposite to the first surface;
a first unit pixel disposed in the substrate and comprising a first photodiode and a second photodiode, a first size of the first photodiode being greater than a second size of the second photodiode;
a second unit pixel disposed in the substrate and comprising a third photodiode and a fourth photodiode, a third size of the third photodiode being greater than a fourth size of the fourth photodiode; and
a capacitor configured to store first charges generated by the second photodiode and second charges generated by the fourth photodiode,
wherein a first light-receiving area of the first photodiode is greater than a second light-receiving area of the second photodiode,
wherein a third light-receiving area of the third photodiode is greater than a fourth light-receiving area of the fourth photodiode, and
wherein the second photodiode is disposed diagonally from the first photodiode on the first surface.

2. The image sensor of claim 1, wherein the capacitor comprises a metal-insulator-metal (MIM) capacitor.

3. The image sensor of claim 2, wherein the second photodiode is in contact with the first photodiode diagonally on the first surface.

4. The image sensor of claim 3, wherein the first photodiode and the second photodiode are configured to receive first light wavelengths corresponding to a first color.

5. The image sensor of claim 4, wherein the third photodiode and the fourth photodiode are configured to receive second light wavelengths corresponding to a second color different from the first color.

6. The image sensor of claim 5, wherein the first unit pixel further comprises a first floating diffusion node and a first reset transistor coupled with the first floating diffusion node,
wherein the second unit pixel further comprises a second floating diffusion node and a second reset transistor coupled with the second floating diffusion node,
wherein the first floating diffusion node is configured to store the first charges generated by the second photodiode, and
wherein the second floating diffusion node is configured to store the second charges generated by the fourth photodiode.

7. The image sensor of claim 6, further comprising:
a device isolation layer configured to isolate the first photodiode and the third photodiode,
wherein the device isolation layer is in contact with the first surface and the second surface.

8. The image sensor of claim 6, further comprising:
a third unit pixel disposed in the substrate comprising a fifth photodiode and a sixth photodiode, a fifth size of the fifth photodiode being greater than a sixth size of the sixth photodiode,
wherein a fifth light-receiving area of the fifth photodiode is greater than a sixth light-receiving area of the sixth photodiode, and
wherein the capacitor is further configured to store third charges generated by the sixth photodiode.

9. The image sensor of claim 8, wherein the fifth photodiode is in contact with the first photodiode diagonally on the first surface.

10. The image sensor of claim 9, further comprising:
a first layer comprising a plurality of metal interconnection lines; and
a second layer,
wherein the substrate is disposed on the second layer, and
wherein the first layer and the second layer are coupled with each other by hybrid bonding.

11. The image sensor of claim 10, wherein the capacitor is disposed between the first photodiode and the second layer, and
wherein the capacitor at least partially overlaps the first photodiode in a third direction perpendicular to the first surface.

12. An image sensor, comprising:
a substrate comprising a first surface and a second surface opposite to the first surface;
a first unit pixel disposed in the substrate and comprising a first photodiode and a second photodiode, a first size of the first photodiode being greater than a second size of the second photodiode;
a second unit pixel disposed in the substrate and comprising a third photodiode and a fourth photodiode disposed in the substrate, a third size of the third photodiode being greater than a fourth size of the fourth photodiode; and
a capacitor configured to store first charges generated by the second photodiode and second charges generated by the fourth photodiode,
wherein a first light-receiving area of the first photodiode is greater than a second light-receiving area of the second photodiode,
wherein a third light-receiving area of the third photodiode is greater than a fourth light-receiving area of the fourth photodiode, and
wherein the first photodiode and the second photodiode are configured to receive light wavelengths corresponding to a first color.

13. The image sensor of claim 12, wherein the first unit pixel is configured to receive a predetermined voltage through the capacitor.

14. The image sensor of claim 13, wherein the first unit pixel further comprises a first reset transistor,
wherein the second unit pixel further comprises a second reset transistor, and
wherein the first reset transistor and the second reset transistor are coupled with the capacitor.

15. The image sensor of claim 14, wherein the second photodiode is in contact with the first photodiode diagonally on the first surface,
wherein the fourth photodiode is in contact with the third photodiode diagonally on the first surface, and
wherein the second photodiode is in contact with the first surface in a first direction parallel to the first surface.

16. The image sensor of claim 15, further comprising:
a first device isolation layer configured to isolate the first photodiode and the second photodiode; and
a second device isolation layer configured to isolate the third photodiode and the fourth photodiode,
wherein the first device isolation layer and the second device isolation layer are in contact with the first surface and the second surface.

17. The image sensor of claim 15, wherein the capacitor comprises a metal-insulator-metal (MIM) capacitor.

18. The image sensor of claim 17, further comprising:
a first layer comprising a plurality of metal interconnection lines; and
a second layer,
wherein the substrate is disposed on the second layer, and
wherein the first layer and the second layer are coupled with each other by hybrid bonding.

19. The image sensor of claim 18, wherein the capacitor is disposed between the first photodiode and the second layer, and
wherein the capacitor at least partially overlaps the first photodiode in a third direction perpendicular to the first surface.

20. An image sensor, comprising:
a first unit pixel comprising a first photodiode, a second photodiode, and a first amplification transistor shared by the first photodiode and the second photodiode;
a second unit pixel comprising a third photodiode, a fourth photodiode, and a second amplification transistor shared by the third photodiode and the fourth photodiode;
a third unit pixel comprising a fifth photodiode, a sixth photodiode, and a third amplification transistor shared by the fifth photodiode and the sixth photodiode; and
a metal-insulator-metal (MIM) capacitor shared by the first unit pixel, the second unit pixel, and the third unit pixel,
wherein the third photodiode is disposed with the first photodiode in a first direction,
wherein the fifth photodiode is disposed with the first photodiode in a second direction perpendicular to the first direction, and
wherein the second photodiode is in contact with the first photodiode in a diagonal direction between the first direction and the second direction.
